(19) United States
(12) Patent Application Publication
(10) Pub. No.: US 2023/0066366 A1
(43) Pub. Date: Mar. 2, 2023

(54) FLEXIBLE SUBSTRATE

(71) Applicants: David Anthony Overton, Hampshire (GB); Ian Matthew Holt, Eastleigh (GB)

(72) Inventors: David Anthony Overton, Hampshire (GB); Ian Matthew Holt, Eastleigh (GB)

(73) Assignee: Splashmaps Ltd, Eastleigh (GB)

(21) Appl. No.: 17/896,311

(22) Filed: Aug. 26, 2022

(30) Foreign Application Priority Data
Aug. 28, 2021 (GB) 2112337.7

(51) Int. Cl. G02F 1/1333; H01L 27/12; H01L 27/32

(52) U.S. Cl. CPC G02F 1/133305; H01L 27/1262; H01L 27/3206

(57) ABSTRACT

A flexible light emitting substrate in accordance with an embodiment hereof includes a controller, a base substrate that carries a data source printed or displayed thereon, which defines a plurality of grid locations, and a data display source provided on, under, or within the base substrate and is wirelessly or wiredly coupled to the controller. Each data display source is associated with a respective grid coordinate or with a specific location or with a position of an object or person relative to a boundary displayed on the base substrate. The embodiment further includes a position sensor for determining the current location of a person or object, and a power source for providing power to the data display source and the controller, where the controller is configured for selectively controlling operation of the data display source based at least partially on the determined current location of the person or object.

### CROSS-REFERENCE TO RELATED PATENT APPLICATIONS

This patent application claims priority to United Kingdom Patent Application No. 2112337.7, filed Aug. 28, 2021, the entire teachings and disclosures of which are incorporated herein by reference thereto.

### FIELD

The present invention relates to flexible substrates with the ability to selectively emit light and/or display data to provide an indication to a user.

### BACKGROUND

Many outdoor pursuits require knowledge of the location of a user, a destination and a route, for example. Conventional paper maps can be used to plot and follow a route from a known starting point to a required destination. Global Navigation Satellite Services (GNSS) systems are also commonly used to provide routing information from an instantaneous position to a required destination. Each of these solutions has its drawbacks. Paper maps can get wet and easily damaged when being used in inclement conditions. Waterproof versions of such maps exist to alleviate this problem, but it can still be difficult to handle and read such maps in strong winds and/or in the dark. GNSS systems are typically compact and easy to read and interpret but they tend to suffer from relatively short battery life and can intermittently lose satellite coverage. The acquisition cost of reliable GNSS systems can also be prohibitive to some users.

Even where GNSS systems are used, they are generally in the form of wrist-worn or hand-held devices and the data displayed thereon is generally not visible to other individuals. The data available on wrist worn devices can be difficult to interpret, particularly where a displayed map may have no frame of reference. Larger GNSS devices can show a more detailed map with environmental features, but these can be heavy and power intensive.

It is against this background that the present invention has arisen.

### BRIEF SUMMARY

Embodiments of the present invention relate to flexible base substrates that carry a map, chart, graph, or other information source, that is capable of portraying information relating to a geographical area. Light emitting or data display sources are embedded, integrated, or attached to the base substrate and can be illuminated to indicate the position of a person or object within the specific geographical area. For example, a sheet map may display geographical features relating to Snowdonia, a national park in Wales. The sheet map may be split into a plurality of grid sections which can be identified by standard grid coordinates, i.e., A4, C6, D5, for example. The light emitting or data display sources are configured to illuminate or otherwise display data to identify the position of a person or object when located in a particular grid section. In other embodiments, the map, chart, graph, or other information source, is carried by an alternative fabric article, i.e., an arm warmer, shirt, sweater, hoody etc. In each case, part of the map, chart, graph, or other information source, may be illuminated or displayed in accordance with the relative position of a person or object within a specific geographical area. While the geographical area could be a wilderness area, for example, it could equally be a whole city, city block, street or individual building.

An aspect of the present invention provides a flexible light emitting substrate comprising: a controller; a base substrate that is deformable in use and carries a map, chart or other data source printed or otherwise displayed thereon which defines a plurality of grid locations identifiable by x and y grid coordinates; at least one illumination or data display source provided on, under or within the base substrate and operably coupled to the controller wirelessly or by a wired connection, each illumination source or data display source of the at least one illumination source or data display source being associated with a respective x or y grid coordinate or with a specific location within an x and y grid coordinate or with a position of an object or person relative to a boundary representative of the map or chart printed or otherwise displayed on the base substrate; a position sensor for determining the current location of a person or object; and a power source for providing power to the controller and the at least one illumination or data display source, wherein the controller is configured for selectively controlling operation of the at least one illumination or data display source based at least partially on the determined current location of the person or object.

The present invention combines functionality and advantages of paper maps and global positioning systems into a single, low-power technology package. The invention is based on a flexible substrate, i.e., a fabric, that can be used to provide the invention in numerous form factors, i.e., sheet maps, tubular structures, clothing etc. The at least one illumination or data display source provides technical functionality and facilitate visibility and interpretation of conventional printed map or chart features while drawing minimal power from the power source. In other words, the invention provides basic location technology into a map structure which may provide significantly improved battery life over conventional GNSS devices.

In one embodiment, the map or chart of the base substrate defines a plurality of grid locations identifiable by x and y grid coordinates. The at least one illumination or data display source comprises an array of data points positioned around the edge of the base substrate. An illumination or data display source associated with a y coordinate and an illumination or data display source associated with an x coordinate may be illuminated as a pair to identify the grid location occupied by an object or person based on the position of the object or person determined by the one or more position sensors.

In the case of a sheet map, the at least one illumination or data display source can identify the location of an object or person in general terms using the grid coordinates and a pair of illumination or data display sources. A viewer of the map can thus immediately determine their general location on the map and plot a route in confidence with knowledge of their approximate current location. In another embodiment, the at least one illumination or data display source comprises an array of data points across the sheet map that may accurately identify and display the location of an object or person on the sheet map.

In one embodiment, the controller and power source are housed within a secondary substrate, the secondary substrate further comprising a secondary location grid associated with the identified grid location of the base substrate, the secondary location grid comprising at least one illumination or data display source defining an array of data points associated with geographical areas defined by the identified grid location of the base substrate, wherein at least one of the data points is configured to signify the position of the object or person within the identified grid location of the base substrate. The secondary substrate may be stitched, or otherwise permanently joined, to the sheet map. In some embodiments, the secondary substrate may be attached to the sheet map by Velcro, press studs, or the like. In such an embodiment, the at least one illumination or data display source may be selectively connected to the controller and power source by way of various electrical connectors.

In one embodiment the location grid may comprise an array of LEDs (or similar) that are mounted on a solid-state circuit board. The fabric map substrate may encapsulate, overlay or otherwise house the solid-state circuit board and the controller and position sensor(s) of embodiments of the present invention.

In one embodiment, one or more biometric sensors are configured to measure instantaneous values of one or more sports performance metrics.

Certain embodiments of the invention may be used to collect data representatives of performance metrics alongside information relating to the position of an object or person. For example, metrics such as heart rate, respiratory rate, oxygen level and stride length may be determined by way of data collected from appropriate sensors. This data may be displayed to the user by way of the at least illumination or data display source, or a separate computing device, i.e., a smart watch or mobile device, or on a separate display forming part of the base substrate or secondary substrate (where applicable).

In one embodiment, the at least one illumination or data display source is configured to overlay a route or trajectory on the printed map or chart. In another embodiment, the at least one data display source may be configured to render a route or trajectory, or other data, on the printed map or chart.

Outdoor sporting and leisure activities such as hiking, ultra-marathons and cycling sportives, require participants to navigate a set route. Physical navigation aids are sometimes provided but these can easily be missed, tampered with, or placed in error. Provision of a route on an arm warmer, shirt, or other item of clothing, that can identify the position of the participant on the route advantageously enables the user to visually identify whether they are on route, or whether they need to correct their course to join the pre-defined route again.

In one embodiment, the at least one illumination or data display source defines an array of data points and at least a subset of the data points defined by the at least one illumination or data display source is configured to display a different coloured light in response to determination of one or more parameter values. In one embodiment, a first of the data points is configured to signify the position of a first object or location on the map or chart and a second of the data points is configured to signify the position of a second object or location on the map or chart.

Different coloured lights may be used to differentiate between different persons and/or objects. In one example, a first participant of a sporting or leisure events can be shown on a map by a first colour and a second participant can be shown on the same map in a different colour. In another example, a location of a lost or injured person can be shown on a map in a first colour and search and rescue personnel can be shown on the same map in a second colour. In yet another example, an object or location can be shown on a map in a first colour and the location of a user of embodiments of the invention can be shown on the same map in a second colour. It will be appreciated that the examples are given merely to demonstrate several ways that different coloured data points can be used to differentiate different types of information.

In one embodiment, a direction indicator and/or distance indicator may be provided to determine the direction or distance of the second object relative to the first object.

The provision of distance and/or direction indicators provides several advantageous benefits. Firstly, while the core embodiments of the invention provide a general indication of location based on a grid-based system, distance and/or direction data may help finetune guidance towards another object and/or person. For example, if a person is known to be located within a specific grid reference, the use of distance and/or distance sensors may help guide a person towards a more specific location. This can be achieved by indicating an approximate distance to a target person and/or object and by indicating an approximate direction to a target person and/or object. Secondly, a pre-determined route may be displayed, electronically or printed, on a substrate and distance and/or direction indicators may provide guidance towards said route or towards checkpoints along said route.

In one embodiment, the controller is activated in response to moving an RFID enabled device into proximity with the controller or other RFID enabled components of embodiments of the invention.

To maximise efficiency of the power source, the controller may utilise a clock functionality to stop drawing power from the power source after a certain period of time from the controller last determining a user interaction with embodiments of the invention. To activate the controller, an RFID, or NFC, enabled device may be moved into proximity with the controller, or other part of an embodiment of the invention. Establishment of a connection between the RFID, or NFC, enabled device with the controller, whether directly or indirectly, may cause the controller to again draw power from the power source for a pre-determined time. A user may also manually elect to power down the controller using a button, switch, or other appropriate input source.

In one embodiment, a time indicator may be provided and configured to determine and display a real time representation of the time elapsed between the first object and second object passing a pre-determined location or position on the map or chart.

Where embodiments of the invention are utilised in conjunction with sporting events, particularly sporting events that require participants to complete multiple laps of a circuit, a time indicator may advantageously provide real time data regarding performance of a participant, or multiple participants. Embodiments of the invention can thus provide a way of gauging the effort required to meet planned lap and/or segment times both visually in terms of actual position along a course or circuit and through data.

In one embodiment, the power source is configured for conductive charging that is activated by moving a conductive charging enabled device into proximity with the power source.

Embodiments of the invention may utilise conductive charging functionality as provided in certain smart phones, and other mobile devices. This enables the power source of embodiments of the invention to remain charged without the user having to physically connect an external power source with the power source. Conductive charging functionality may be disabled until such time that the charge level of the power source falls below a first pre-determined level, i.e., 30%. Conductive charging may then be activated until such time that the charge level of the power source exceeds a second pre-determined level, i.e., 70%. This way, the charge level of the power source is maintained without unduly burdening the charge level of a power source associated with the mobile device.

In one embodiment, the communication means is configured to exchange data with other devices such that data representative of such other devices can be indicated on the map or chart of the base substrate through one or more of the data points of the array.

The map or chart of the base substrate may be used to determine its own location or to guide a user to the location of another person and/or object. The location of another person and/or object may be determined by a mobile device associated with that person and/or object. Data representative of the location of the person and/or object may be transmitted to the communication means and the at least one illumination or data display source may be illuminated or represented on the map or chart to represent the location of the person and/or object. As described above, the location of the other person and/or object may be identified alongside the location of the map.

Further areas of applicability of the present invention will become apparent from the detailed description provided hereinafter. The detailed description and specific examples, while indicating the preferred embodiment of the invention, are intended to be given by way of example only.

### BRIEF DESCRIPTION OF THE DRAWINGS

Aspects and embodiments of the invention will now be described by way of reference to the following drawings.

FIG. 1 illustrates a first embodiment of the invention embodied in a sheet map and in a folded-out configuration;

FIG. 2 illustrates the first embodiment of the invention in a folded-up configuration;

FIG. 3 illustrates the first embodiment of the invention in a scrunched-up configuration;

FIGS. 4a and 4b illustrates a second embodiment of the invention embodied in a tubular structure, i.e., an arm warmer;

FIG. 5 illustrate the second embodiment of the invention as worn by a user;

FIGS. 6a and 6b illustrates a third embodiment of the invention embodied in an item of clothing, i.e., a shirt;

FIG. 7 illustrates an exemplary technical architecture of embodiments of the invention;

FIG. 8 illustrates a flow diagram of a process for identifying a grid location of an object or person;

FIG. 9 illustrates a flow diagram of a process for identifying the relative positions of a first object or person and a second object or person; and

FIG. 10 illustrates a flow diagram of a process for identifying density of objects or persons at pre-determined locations.

### DETAILED DESCRIPTION

The following description of the preferred embodiment(s) is merely exemplary in nature and is no way intended to limit the invention, its application, or uses.

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the exemplified embodiments. Accordingly, the invention expressly should not be limited to such exemplary embodiments illustrating some possible non-limiting combination of features that may exist alone or in other combinations of features; the scope of the invention being defined by the claims appended hereto.

A first embodiment of the invention is illustrated in FIGS. 1 to 3. A sheet map 10 comprises a fabric substrate 12 that carries a map or chart 14. The map or chart 14 may be printed, sewn, or otherwise attached to the fabric substrate 12. The map or chart 14 is split into grid sections 16, with each grid section being identifiable by a co-ordinate system. In the illustrated embodiment, the vertical axis 18 of the map or chart 14 identifies each column of grid sections 16 by a letter, i.e., A, B, C etc and each row of grid sections 16 is identified by a number, i.e., 1, 2, 3 etc. The bottom left-hand corner of the grid 16 being identified as A1 with the letter increasing incrementally horizontally to the right of the A1 grid section and the number increasing incrementally vertically upwards from the A1 grid section.

The sheet map 10 comprises a plurality of light emitting sources 20, e.g., light emitting diodes (LEDs) organic light emitting diodes (OLEDs) or organic light emitting cells (OLECs). Other illumination sources that facilitate the functionality of embodiments of the invention may also be used while remaining within the scope of the claimed invention. Illustrated embodiments show a sheet map 10 with one LED positioned in the immediate vicinity of each letter and number of the co-ordinate system. Where the term LED is used it can be replaced with OLED, or OLEC, or any other term that may be used to describe a suitable illumination source without departing from the scope of the claimed invention. Alternatively, each grid section may incorporate a LED within its boundary. Each LED 20 is operably connected to a controller 22 which is configured to control when each LED 20 is illuminated, or not. The controller draws power from a power source 24. The controller uses position sensor data to determine which LED to illuminate. The position data may be collected by a position sensor 26 that is embedded in the sheet map 10. Alternatively, position data may be collected by a position data sensor forming part of a separate device, i.e., smart phone, dedicated Global Positioning System or Global Navigation Satellite System (GNSS) device, or other device provided with position sensing functionality. The controller 22 uses the position data to determine the location of an object or person relative to a datum. If the location of the object or person falls within the geographical location represented by the map or chart 14, the controller 22 determines the location of the object or person relative to the datum to determine its grid location. The controller 22 subsequently causes the relevant LEDs 20 to illuminate to visually identify the position of the object or person on the sheet map 10.

The LEDs 20 may be configured to emit different coloured lights depending on the data to be represented. For example, in a search and rescue situation, the location of a person requiring assistance may be represented by a first colour, i.e., red, and the location of search and a search and rescue team may be represented by a different colour, i.e., green. The LEDs 20 may also be configured to emit light of varying characteristics depending on the relative distance between two persons or objects. For example, if two objects or persons are located within a single grid location, the LEDs 20 may emit different light intensities depending on the relative distance between the two objects or persons. The LEDs 20 may also blink/flash at different frequencies or emit different coloured lights depending on the relative distance between the two objects or persons. Other data may be represented by LEDs 20 such as to indicate to a user that they should proceed in a certain direction to reach a location within the boundary displayed on the sheet map 10.

The controller 22 is provided with communications means to enable transfer of data with an external device. This may be by way of Bluetooth®, WiFi, or other network connectivity, or by way of a cabled connection with an external device.

The sheet map 10 further comprises a fold out legend 28 that provides standard mapping keys. The legend 28 comprises two layers of fabric defining a pouch therebetween within which the controller 22, power source 24 and positions sensor 26 may be embedded. The legend 28 may further comprise a display 30. The display 30 is associated with the grid section 16 determined by the controller 22 to be occupied by the object or person. The display 30 is defined by a plurality of LEDs 32 in the form of an array. Each grid section 16 is further divided into sub-sections to facilitate accurate identification of the position of an object or person. Each sub-section of the selected grid section 16 is represented by the display 30. For example, a grid section 16 may be divided into nine sub-sections. The display 30 may comprise nine LEDs 32 with each LED being associated with a respective sub section of the selected grid section 16. When an object or person is in grid section C4 its accurate position relative to the datum is determined by the controller 22. The general grid location C4 is represented on the main body of the sheet map 10 by illumination of LEDs 20 associated with column C and row 4. The display 30 is updated in real time as the object or person moves within the relevant grid section. For example, if the object or person enters the grid section from North, one of the LEDs 32 of the top row of the display 30 is illuminated depending on the location of the object or person relative to the datum. As the object or person moves within the grid section, a single LED 32 is illuminated at any one time to identify the general position of the object or person within the grid section 16. Each LED 32 may be assigned light emitting characteristics in accordance with different types of data that such LEDs 32 are intended to provide to a user. For example, each LED 32 in the array may be configured to correspond to a particular direction in which the user is required to proceed to reach a location within the boundary. The LED 32 may emit a solid light, or it may flash at varying on/off intervals. While the display 30 is described and illustrated as comprising an array of LEDs 32, the display 30 could also comprise a single display source configured to emit light or display data on any part of the display 30. For example, an electrophoretic display may render the grid location in which the person or object is located and identify on the display the accurate position of the person or object. The display 30 may also be configured to emit a light or display an indicator at any point on the display 30 to identify an accurate position of the person or object.

The legend 28 may further comprise an electronic compass 34 to assist the user in identifying the direction in which they are travelling. The electronic compass 34 is operably connected to the controller 22. The electronic compass 34 may further display a target direction to assist the user in navigating towards a place, object or location.

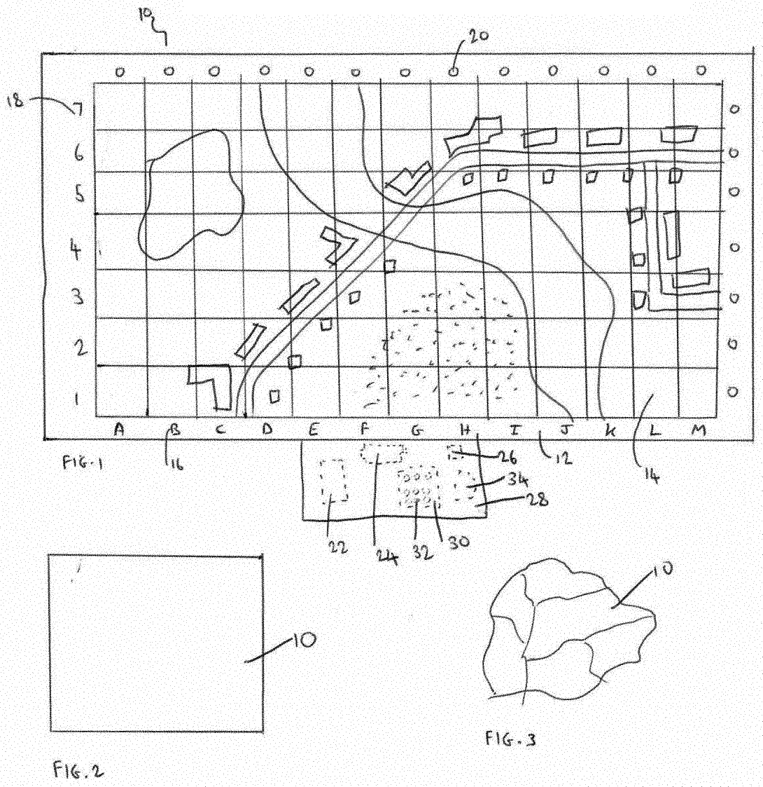

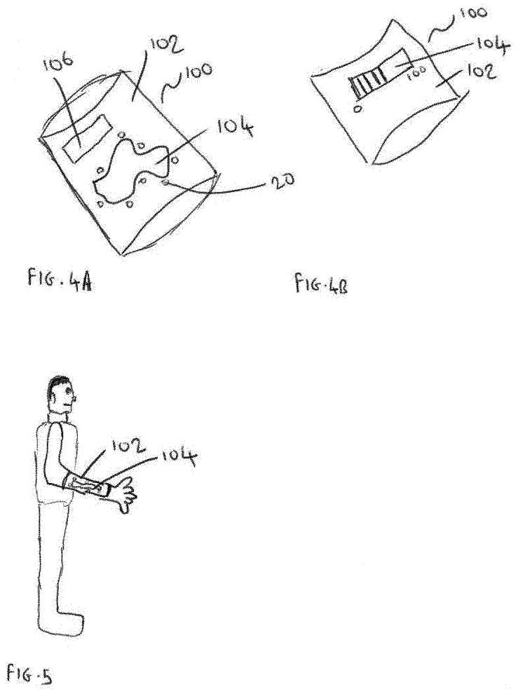

The sheet map 10 can be folded up (as shown in FIG. 2) or scrunched up (as shown in FIG. 3). The flexibility of the sheet map 10 means that it can be stored quickly and easily within a pouch or pocket of a bag or clothing.

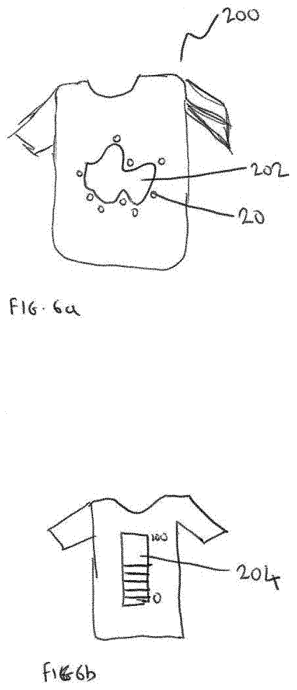

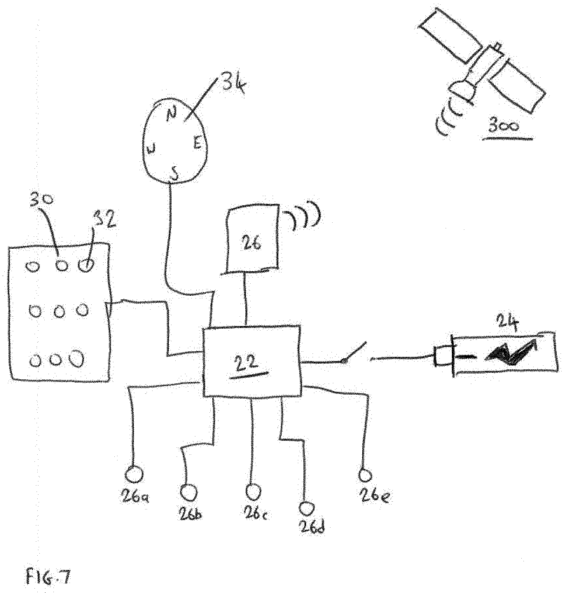

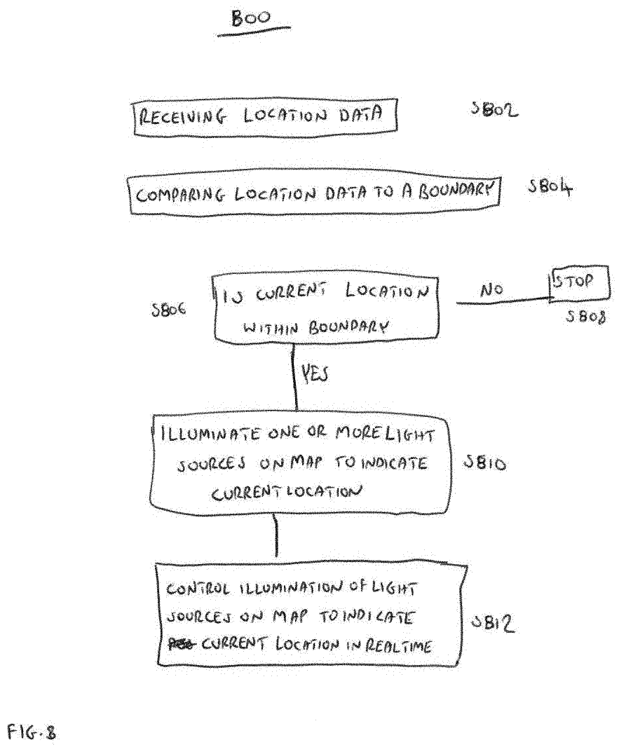

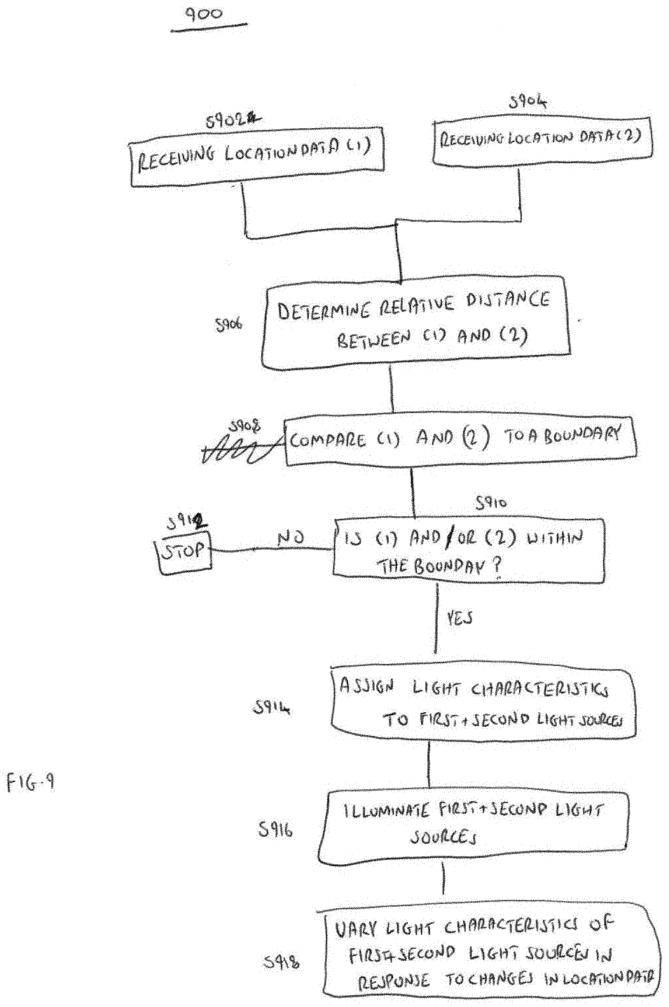

In another embodiment of the invention, as illustrated in FIGS. 4 and 5, a tubular structure 100, i.e., an arm warmer, comprises a sleeve 102 that can be worn on the upper or lower arm of a user, for example (the arm warmer is shown worn on the lower arm of the user in FIG. 5). The sleeve 102 may carry a map, chart, graph, or other information source 104 that is printed, sewn, or otherwise attached or integrated to, on or within the sleeve 102. A plurality of LEDS 20 may be embedded within the sleeve 102 and operably connected to the controller 22. The controller 22 may further determine the position of the sleeve 102 through either an embedded position sensor 26 or a position sensor of a smart phone, dedicated GNSS enabled device, or other GNSS enabled device. Other sensors that measure various metrics, i.e., heart rate, accelerometer, speed, direction etc, may also be monitored by the controller 22. Such sensors may be embedded within the sleeve or connected to the controller 22 by way of Bluetooth or ANT+, for example. In one embodiment, the sleeve 102 provides a data display source 106 that indicates to the user his/her progress along a pre-defined route. The data display source 106 may comprise a bar chart that indicates a percentage completion of the pre-defined route or a map, for example. The bar chart may be accompanied by a percentage shown in numbers. The data display source 106 may also indicate the user's heart rate, pace, speed, and direction, for example. The data display source may be an OLED or OLEC display that shows progress in an incremental fashion.

In yet another embodiment of the invention, as illustrated in FIGS. 6a and 6b, an item of clothing 200, i.e., a shirt, carries a map, chart, graph, or other information source 202 that is printed, sewn, or otherwise attached to the shirt 200. A plurality of LEDs 20 may be embedded within the shirt 200 and operably connected to the controller 22. The controller 22 may further determine the position of the shirt 200 through either an embedded position sensor 26 or a position sensor of a smart phone, dedicated GNSS device, or other GNSS enabled device. Other sensors that measure various metrics, i.e., heart rate, accelerometer, speed, direction etc, may also be monitored by the controller 22. Such sensors may be embedded within the sleeve or connected to the controller 22 by way of Bluetooth or ANT+, for example. In one embodiment, the item of clothing 200 provides a data display source 204 that indicates to a viewer, the progress of a person or object along a pre-defined route. The data display source 204 may comprise a bar chart that indicates a percentage completion of the pre-defined route or a map, for example. The bar chart may be accompanied by a percentage shown in numbers. The data display source 204 may also indicate the user's heart rate, pace, speed, and direction, for example. The data display source may be an OLED or OLEC display that shows progress in an incremental fashion.

In each of the embodiments illustrated in FIGS. 4 to 6, the data display source 106, 204 may indicate health or performance metrics of the wearer. For example, the data display source 106, 204 may provide a coloured condition metric of the wearer. This may be useful in mass participation events and for those engaged in outdoor pursuits. The coloured condition metric would be visible to others in the vicinity of the wearer of the arm warmer or clothing 100, 200. For example, heart rate and respiratory sensors may be used to collect heart rate and respiratory data, along with other data, and the controller 22 may use such data to generate a health or performance score. The score may be represented in terms of a colour. Green may represent that the wearer is healthy and at minimal risk of a medical event. Orange may represent that the wearer is operating outside of their base fitness level and is at heightened risk of a medical event. Red may represent that the user is at high risk of suffering a medical event prior to completion of the planned activity. The controller 22 may use GNSS position data to determine the wearer's current location and to compare this with the finish point of a pre-determined route. If the wearer is close to completion of the pre-determined route and his/her heart and respiratory rate are well above baseline metrics, the health or performance metric may nevertheless be shown in green as the wearer will likely complete the activity within a short period of time whereas if the current position of the wearer is a long way from the anticipated finish point of the pre-determined route, the health or performance metric may be shown as red. Furthermore, in a mass participation event, wearers who are determined to be at risk of suffering a medical event during, or upon completion of, the event may have a health or performance metric shown in red to: a) enable the wearer to take a rest and recover before continuing; and/or b) indicate to others that the wearer may need medical attention. The position of the wearer may be determined by the position sensor 26 and transmitted to a central monitoring system and/or to a pre-determined emergency contact if a health or performance metric threshold is exceeded.

The technical architecture of embodiments of the invention is illustrated in FIG. 7. The controller 22 comprises control circuitry, volatile and non-volatile memory, and a communications interface. The controller 22 routes power from the power source 24 to other components of embodiments of the invention. Notionally a satellite 300 of a GNSS system transmits satellite signals to Earth. The satellite 300 transmits a satellite navigation signal to Earth on a signal propagation path, which signal can be received by a position sensor 26 of embodiments of the invention. The received satellite signal is used by the controller 22 to determine a current position of a person or object associated with the position sensor 26. If the current position of the person or object falls within a geographical boundary defined by the map, chart, graph, or other information source, LEDs that are representative of the current position of the person or object are illuminated to identify such position on the map, chart, graph, or other information source. The display 30 is configured to display the accurate position of a person or object as determined by the controller 22 when the person or object is determined be within a specific grid location. The electronic compass 34 determines the direction that the person or object is travelling or the direction which a person is required to travel towards another person or object.

Should the person or object fall outside the area of the map, illuminated indicators may flash on the corresponding area of the display to indicate the nearest side of the map to that person or object. The on/off frequency may be variable to indicate the distance of the person or object from the area of the map. For example, if the person or object is 1 mile away from entering the area of the map, the relevant LED 20 may blink every 1 second and if the person or object is 2 miles away from entering the area of the map, the relevant LED 20 may blink every two seconds, for example.

Non-volatile memory of the controller 22 may store GNSS data to facilitate establishment of a connection between a satellite and the position sensor 26. Data representative of a datum and general mapping source information may also be stored in the non-volatile memory of the controller 22.

The communications interface may comprise a receiver and transmitter for exchanging data with an external computing device over known protocols such as Bluetooth, ANT+, WiFi, 3G, 4G, 5G and GSM. Data representative of updates to GNSS and mapping data may be pushed to the controller 22 on a periodic basis. Tracking information regarding movement of an object or person over time may be transmitted from the controller to external computing devices. Data may also be shared between controllers 22 of respective devices according to embodiments of the invention. For example, location data of multiple devices may be shared to facilitate creation of a heatmap.

FIG. 8 illustrates a process 800 of identifying a grid location of an object or person according to an embodiment of the invention. The process starts at step S802 by receiving, by a position sensor 26, data representative of a current geographical location of the position sensor 26. At step S804, the received data is compared to data indicative of a boundary. The process proceeds to step S806 if the current geographical location is determined to be within the boundary. The process terminates at step S808 if the current geographical location is determined to be outside of the boundary. At step S806 the controller 22 causes one or more LED(s) to illuminate to indicate on a map, chart, graph, or other information source, a current location of a person or object represented by the position sensor. At step S810, the position of the object or person associated with the position sensor 26 is monitored. At step S812, the controller causes a change in the illuminated LEDs as the position of the object or person associated with the position sensor 26 changes in real time.

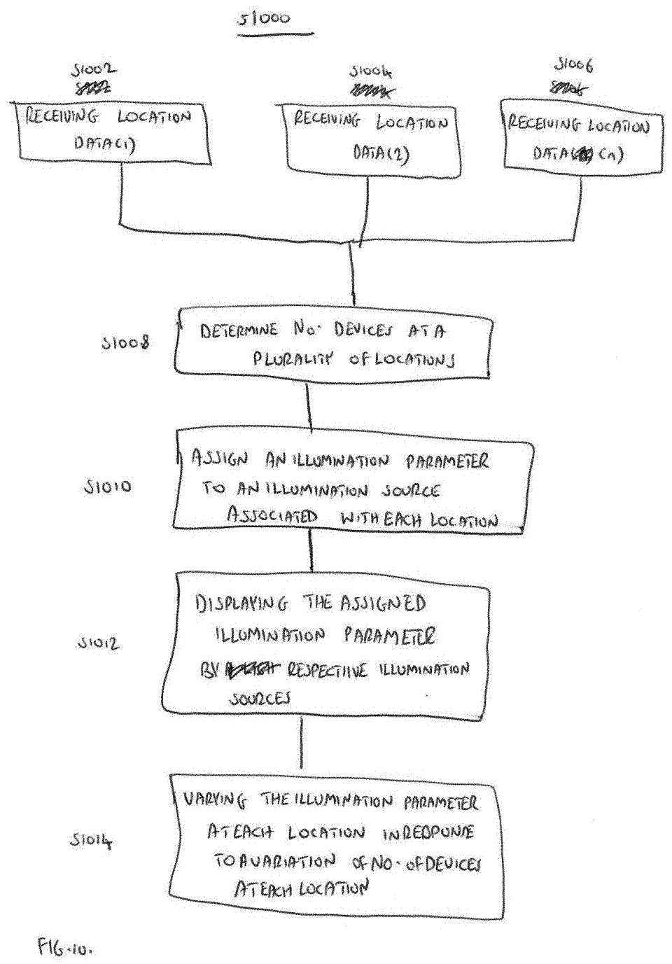

FIG. 9 illustrates a process 900 for identifying relative positions of a first object or person and a second object or person. The process starts at step S902 by receiving, by a first position sensor 26a, data representative of a current geographical location of the first position sensor 26a. At step S904, the second position sensor 26b receives data representative of a current geographical location of the second position sensor 26b. At step S906, the controller 22 determines a relative distance between the first position sensor 26b and second position sensor 26b. At step S908, the controller 22 compares the geographical location of the first position sensor 26a and second position sensor 26b to data indicative of a boundary. At step S910, the controller 22 causes one or more LED(s) to illuminate on a map, chart, graph, or other information source in respect of either, or both, of the position of a first object or person associated with the first position sensor 26a and the position of a second object or person associated with the second position sensor 26b. At step S912 a first light characteristic is assigned to a first LED associated with the first position sensor 26a and a second light characteristic is assigned to a second LED associated with the second position sensor 26b. For example, the first LED may emit a red light and the second LED may emit a green light. Alternatively, the first LED may emit a solid light and the second LED may emit a blinking or flashing light. At step S914, either the characteristic of the first LED or second LED may be varied in real time to identify a change in position of the first position sensor 26a relative to the second position sensor 26b.

FIG. 10 illustrates a process 1000 for identifying a density of objects or persons at a location. The process starts at step S1002 by receiving by a first position sensor 26a data representative of a current geographic location of the first position sensor 26a. At step S1004 a second position sensor 26b receives data representative of a current geographic location of the second position sensor 26b. At step S1006 a n^{th} position sensor 26ⁿ receives data representative of a current geographic location of the n^{th} position sensor 26ⁿ. At step S1008 the data representative of the then current geographic location of the first position sensor 26a, second position sensor 26b and n^{th} position sensor 26ⁿ is collated to determine a quantity of position sensors 26a, b, . . . n at a plurality of locations. At step S1010 an illumination parameter associated with the plurality of illumination sources 20 is assigned to each location. At step S1012 the illumination parameter is displayed by an illumination source 20 to represent the density of objects or person at each location. At step S1014 the illumination parameter is varied dependent on the then current quantity of position sensors 26a, b, . . . n at each location.

The above embodiments are exemplary only, and other possibilities and alternatives within the scope of the appended claims will be apparent to those skilled in the art. For example, reference to LEDs is not intended to be limiting and LEDs are given only as one example of light emitting or data display source that can be used in embodiments of the invention. It will be appreciated that electrophoretic display screens may be used to render a map, chart, or other information display source. Such display screens may be dynamically updated to record and indicate the real time position of one or more objects or persons and/or to update the map, chart or information display source as the object or person represented on the map, chart or information display changes location.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A flexible light emitting substrate comprising:
a controller;
a base substrate that is deformable in use and carries a map, chart or other data source printed or otherwise displayed thereon which defines a plurality of grid locations identifiable by x and y grid coordinates;
at least one illumination or data display source provided on, under, or within the base substrate and operably coupled to the controller wirelessly or by a wired connection, each illumination source or data display source of the at least one illumination source or data display source being associated with a respective x or y grid coordinate or with a specific location within an x and y grid coordinate or with a position of an object or person relative to a boundary representative of the map or chart printed or otherwise displayed on the base substrate;
a position sensor for determining the current location of a person or object; and
a power source for providing power to the controller and the at least one illumination or data display source,
wherein the controller is configured for selectively controlling operation of the at least one illumination or data display source based at least partially on the determined current location of the person or object.

2. The flexible light emitting substrate of claim 1, wherein the at least one position sensor is a GNSS sensor.

3. The flexible light emitting substrate of claim 1, wherein the base substrate is formed from waterproof or water-resistant fabric.

4. The flexible light emitting substrate of claim 1, wherein the at least one illumination or data display source comprises a plurality of illumination sources positioned around the edge of the base substrate.

5. The flexible light emitting substrate of claim 4, wherein an illumination source associated with a x coordinate and an illumination source associated with a y coordinate are illuminated as a pair to identify the grid location occupied by an object or person based on the position of the object or person determined by the one or more positions sensors.

6. The flexible light emitting substrate of claim 1, wherein the at least one data display source comprises an electrophoretic display.

7. The flexible light emitting substrate of claim 1, wherein the controller and power source are housed within a secondary substrate, the secondary substrate further comprising a secondary location grid associated with the identified grid location of the base substrate, the secondary location grid comprising a plurality of illumination sources associated with geographical areas defined by the identified grid location of the base substrate, wherein one of the plurality of illumination sources is illuminated to signify the position of the object or person within the identified grid location of the base substrate.

8. The flexible light emitting substrate of claim 1, wherein the base substrate comprises a sheet map.

9. The flexible light emitting substrate of claim 1, wherein the base substrate comprises a tubular structure.

10. The flexible light emitting substrate of claim 1, wherein the based substrate comprises an item of clothing.

11. The flexible light emitting substrate of claim 1, further comprising one or more biometric sensors configured to measure instantaneous values of one or more sports performance metrics.

12. The flexible light emitting substrate of claim 1, further comprising communications means for exchanging data with one or more external devices and/or networks.

13. The flexible light emitting substrate of claim 1, wherein the at least one illumination or data display source is configured to overlay a route or trajectory on the printed map or chart.

14. The flexible light emitting substrate of claim 1, wherein the at least one illumination or data display source comprises an array of data points and each data point is configured to display a different coloured light in response to determination of one or more parameter values.

15. The flexible light emitting substrate of claim 13, wherein a first data point is configured to signify the position of a first object or location on the map or chart and a second data point is configured to signify the position of a second object or location on the map or chart.

16. The flexible light emitting substrate of claim 14, further comprising a direction indicator and/or distance indicator to determine the direction or distance of the second object relative to the first object.

17. The flexible light emitting substrate of claim 14, further comprising a time indicator configured to determine and display a real time representation of the time elapsed between the first object and second object passing a pre-determined location or position on the map or chart.

18. The flexible light emitting substrate of claim 1, wherein the controller is activated in response to moving an RFID enabled device into proximity with the controller.

19. The flexible light emitting substrate of claim 1, wherein the power source is configured for conductive charging that is activated by moving a conductive charging enabled device into proximity with the power source.
